(19) United States
(12) Patent Application Publication
(10) Pub. No.: US 2015/0122295 A1
(43) Pub. Date: May 7, 2015

(54) SUBSTRATE PROCESSING APPARATUS

(71) Applicant: Ebara Corporation, Tokyo (JP)

(72) Inventors: Masafumi Inoue, Tokyo (JP); Takayoshi Meguro, Tokyo (JP)

(21) Appl. No.: 14/520,861

(22) Filed: Oct. 22, 2014

(30) Foreign Application Priority Data
Nov. 5, 2013 (JP) 229419/2013

(51) Int. Cl. H01L 21/67

(52) U.S. Cl. CPC H01L 21/67253; H01L 21/67219
USPC 134/61

(57) ABSTRACT

Damage to a substrate in a substrate processing apparatus is effectively suppressed. The substrate processing apparatus includes a polishing unit polishing a substrate, a cleaning unit cleaning and drying the substrate polished by the polishing unit, and a conveying unit conveying the substrate in the polishing unit and the cleaning unit. The substrate processing apparatus further includes a measuring section 5A measuring a standby time of each substrate for which the substrate stands by in each of the polishing unit, the cleaning unit and the conveying unit, and a determining section 5B comparing the standby time measured by the measuring section 5A and a set time set for each unit independently and determining that an error occurs if the standby time exceeds the set time.

### CROSS-REFERENCE TO RELATED APPLICATION

This application is based upon and claims the benefit of priority of the prior Japanese Patent Application No. 2013-229419, filed on Nov. 5, 2013, the entire contents of which are incorporated herein by reference.

### TECHNICAL FIELD

The present invention relates to a substrate processing apparatus.

### BACKGROUND ART

In recent years, in order to perform various kinds of processing on a substrate such as a semiconductor wafer, a substrate processing apparatus is used. Examples of a substrate processing apparatus include a CMP (chemical mechanical polishing) apparatus for polishing a substrate.

A CMP apparatus includes a polishing unit for polishing a substrate, a cleaning unit for cleaning and drying the substrate, a loading/unloading unit for delivering the substrate to the polishing unit and receiving the substrate cleaned and dried by the cleaning unit, and the like. The CMP apparatus further includes a conveying unit for conveying the substrate in the polishing unit, the cleaning unit, and the loading/unloading unit. The CMP apparatus performs the processes of polishing, cleaning, and drying sequentially, while the conveying unit conveys the substrate.

However, if a malfunction occurs in some units of a CMP apparatus, it is difficult to continue a series of processes. This causes a substrate to stand by in the CMP apparatus for a long time. As a result, a surface of the substrate may be damaged by corrosion, etc. A substrate to be a processing target in the substrate processing apparatus is high-priced, and thus, it is preferable to recover such a substrate in as reusable a state as possible.

In the conventional technique, even if a malfunction in some part of a substrate processing apparatus hinders a series of processes on a substrate from continuing, the whole of the apparatus is not stopped and some processing of the substrate is continued to recover the substrate immediately. Therefore, it is known that a risk that processing the substrate is impossible is reduced in the conventional technique.

### CITATION LIST

### Patent Literature

Patent Literature 1: Japanese Patent Laid-Open No. 2009-200476

In the conventional technique, it is not considered to effectively suppress damage to a substrate in a substrate processing apparatus.

That is, if a malfunction occurs in some units of the substrate processing apparatus, a substrate to pass through the malfunctioning unit afterwards is made to stand by in the substrate processing apparatus since the subsequent processing cannot be continued. However, a time period in which the substrate is allowed to stand by is not fixed. Such a time period varies depending on a state of the processing of the substrate.

For example, even if, due to generation of a standby time, a surface of a substrate not having been polished is damaged in some degree by corrosion, etc., the surface of the substrate is scraped in the subsequent polishing process, and thus, it hardly causes a problem, relatively.

In contrast, in a substrate in a standby state before the cleaning process and after the polishing process, the surface of the substrate is damaged by corrosion, etc. due to generation of a standby time, and thus, such a substrate is not preferable.

Therefore, an object of the present invention is to effectively suppress damage to a substrate in a substrate processing apparatus.

### SUMMARY OF INVENTION

An embodiment of a substrate processing apparatus of the present invention has been made in view of the above problem, and the substrate processing apparatus comprises: a polishing unit configured to polish a substrate; a cleaning unit configured to clean and dry the substrate polished by the polishing unit; a conveying unit configured to convey the substrate in the polishing unit and the cleaning unit; a measuring section configured to measure a standby time of each substrate for which the substrate stands by in each of the polishing unit, the cleaning unit, and the conveying unit; and a determining section configured to compare the standby time measured by the measuring section and a set time set for the polishing unit, the cleaning unit and the conveying unit, independently, and determine that an error occurs if the standby time exceeds the set time.

Furthermore, the substrate processing apparatus may further comprise a loading/unloading unit configured to deliver the substrate to the polishing unit and receive the substrate cleaned and dried by the cleaning unit, and the conveying unit may convey the substrate in the polishing unit, the cleaning unit, and the loading/unloading unit.

Moreover, the substrate processing apparatus may further comprise an error processing section configured to display, if the determining section determines that an error occurs, an image representing the substrate processing apparatus on a displaying interface, and display an image specifying a unit in which a substrate that is the error object is standing by on the image representing the substrate processing apparatus.

Furthermore, if the determining section determines that an error occurs, the error processing section may specify a unit causing the standby time to exceed the set time among a plurality of units included in the image representing the substrate processing apparatus, and display the specified unit such that the unit can be identified from the other units.

Moreover, if the determining section determines that an error occurs, the error processing section may display a conveying route of the substrate that is the error object on the displaying interface.

According to the present invention described above, it is possible to effectively suppress damage to a substrate in a substrate processing apparatus.

### BRIEF DESCRIPTION OF DRAWINGS

FIG. 1 is a plan view illustrating an entire configuration of a substrate processing apparatus according to the present embodiment;

FIG. 2 is a schematic perspective view illustrating a polishing unit;

FIG. 3 is a diagram illustrating an example of a conveying route of a wafer W in the substrate processing apparatus;

FIG. 4 is a diagram illustrating a state where conveying wafers W is delayed;

FIG. 5 is a diagram illustrating functional blocks of the substrate processing apparatus;

FIG. 6 is a diagram illustrating an example of standby times of a wafer in units;

FIG. 7 is a diagram illustrating an example of a standby time limit DB 5C; and

FIG. 8 is a diagram illustrating a processing flow of the substrate processing apparatus.

### DESCRIPTION OF EMBODIMENTS

Hereinafter, descriptions will be given of a substrate processing apparatus according to an embodiment of the present invention on the basis of the drawings. Hereinafter, a CMP apparatus will be described as an example of the substrate processing apparatus, but the present invention is not limited to this. Moreover, in the following descriptions, a substrate processing apparatus including a loading/unloading unit 2, a polishing unit 3, and a cleaning unit 4 is provided, but the present invention is not limited to this.

<Substrate Processing Apparatus>

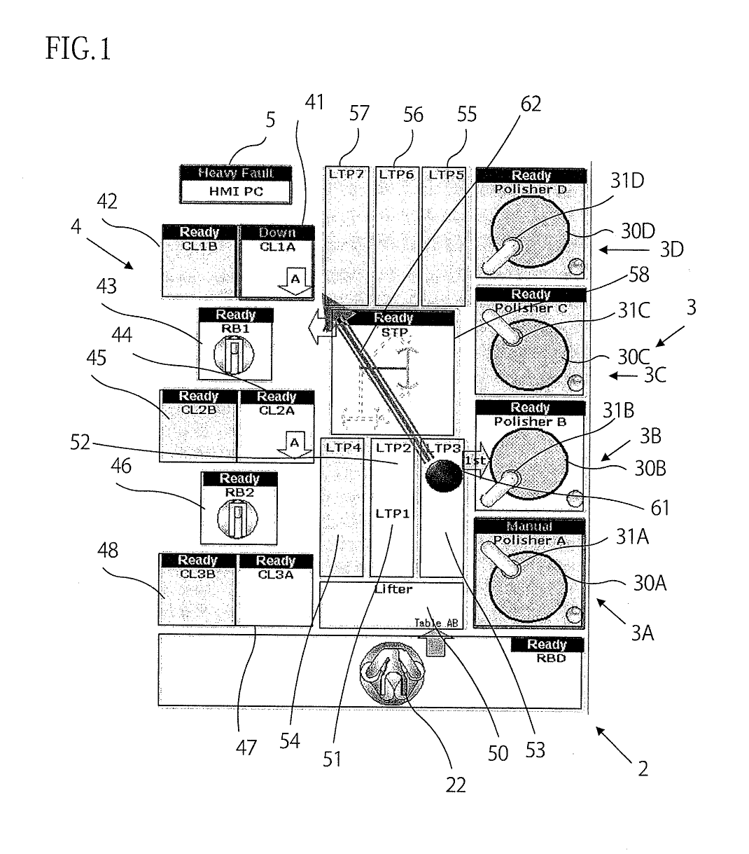

FIG. 1 is a plan view illustrating an entire configuration of a substrate processing apparatus according to an embodiment of the present invention. As illustrated in FIG. 1, the substrate processing apparatus includes a loading/unloading unit (RBD) 2, a polishing unit 3, and a cleaning unit 4. The loading/unloading unit 2, the polishing unit 3, and the cleaning unit 4 are independently assembled, and air is exhausted therefrom independently. The cleaning unit 4 includes a controlling section (HMI) 5 controlling substrate processing operations. The controlling section 5 includes a unit control board (power supply board). The polishing unit 3, the cleaning unit 4, and the loading/unloading unit 2 each include a conveying unit conveying a substrate (conveying robot, conveying mechanism).

<Loading/Unloading Unit>

In the loading/unloading unit 2, a conveying robot (loader, conveying mechanism) 22 conveying a wafer is installed. The conveying robot 22 conveys a wafer that is inserted in a wafer cassette to the polishing unit 3, and also conveys a wafer that is processed by the cleaning unit 4 to the wafer cassette. The conveying robot 22 includes two upper and lower hands. The conveying robot 22 uses the upper hand for returning a processed wafer to the wafer cassette, and uses the lower hand for extracting an unprocessed wafer from the wafer cassette. Accordingly, the conveying robot 22 can use the upper and lower hands appropriately. Furthermore, the lower hand of the conveying robot 22 is configured to rotate around an axial center thereof so that the lower hand can reverse a wafer.

The loading/unloading unit 2 is a region requiring the cleanest condition. The inside of the loading/unloading unit 2 is kept at a pressure higher than that in any of the outside of the substrate processing apparatus, the polishing unit 3, and the cleaning unit 4, all the time. The polishing unit 3 is the dirtiest region since the polishing unit 3 uses slurry as polishing solution. Inside the polishing unit 3, therefore, a negative pressure is formed which is kept lower than the internal pressure of the cleaning unit 4. In the loading/unloading unit 2, a filter fan unit (not illustrated) including a clean air filter such as a HEPA filter, a ULPA filter, a chemical filter or the like is disposed. The filter fan unit blows off clean air from which particles, a poisonous vapor and a poisonous gas have been removed, all the time.

<Polishing Unit>

The polishing unit 3 is a region where a wafer is polished (flattened). The polishing unit 3 includes a first polishing unit (PL-A) 3A, a second polishing unit (PL-B) 3B, a third polishing unit (PL-C) 3C, and a fourth polishing unit (PL-D) 3D. As illustrated in FIG. 1, the first polishing unit 3A, the second polishing unit 3B, the third polishing unit 3C, and the fourth polishing unit 3D are arranged along a longitudinal direction of the substrate processing apparatus.

The first polishing unit 3A includes a polishing table 30A to which a polishing pad having a polishing surface is attached, and a top ring 31A for holding a wafer and polishing a wafer while being pressed against the polishing pad on the polishing table 30A.

Similarly, the second polishing unit 3B includes a polishing table 30B to which a polishing pad is attached and a top ring 31B. The third polishing unit 3C includes a polishing table 30C to which a polishing pad is attached and a top ring 31C. The fourth polishing unit 3D includes a polishing table 30D to which a polishing pad is attached and a top ring 31D.

The first polishing unit 3A, the second polishing unit 3B, the third polishing unit 3C and the fourth polishing unit 3D have a configuration identical to one another, and thus, the description of the first polishing unit 31A will be given below.

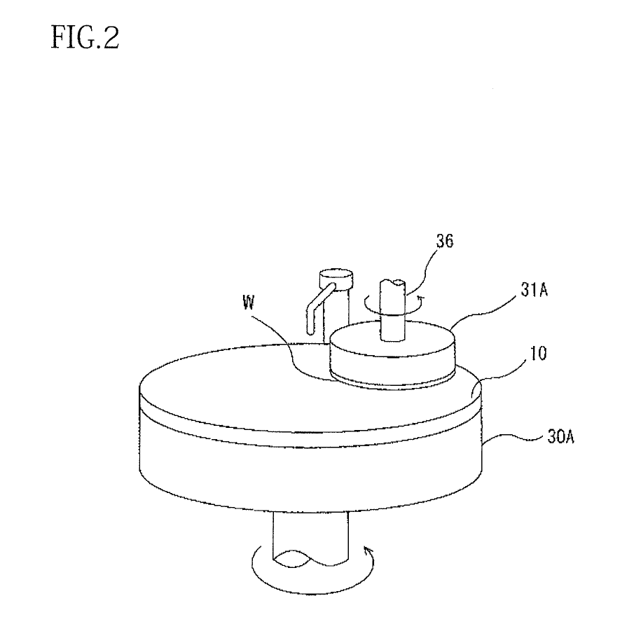

FIG. 2 is a schematic perspective view illustrating the first polishing unit 3A. The top ring 31A is supported by a top ring shaft 36. A polishing pad 10 is attached to an upper surface of the polishing table 30A. The upper surface of the polishing pad 10 forms a polishing surface for polishing a wafer W. Alternatively, a fixed abrasive grain can be used, instead of the polishing pad 10. As indicated by arrows, the top ring 31A and the polishing table 30A are rotated around each axial center thereof. A wafer W is sucked in vacuum to be held on a lower surface of the top ring 31A. At the time of the polishing, polishing solution is supplied from a polishing-solution supplying nozzle to the polishing surface of the polishing pad 10, the wafer W to be polished is pressed against the polishing surface by the top ring 31A, and thus, the wafer W is polished.

Next, descriptions will be given of a conveying mechanism for conveying a wafer, in the polishing unit 3. As illustrated in FIG. 1, adjacently to the first polishing unit 3A and the second polishing unit 3B, a Lifter 50, an LTP1 51, an LTP2 52, an LTP3 53, and an LTP4 54 are provided. The wafer W is conveyed from the loading/unloading unit 2, through the Lifter 50, the LTP1 51, the LTP2 52, the LTP3 53, and the LTP4 54, to the first polishing unit 3A and the second polishing unit 3B. The wafer W having been polished by the first polishing unit 3A and the second polishing unit 3B is conveyed, through the LTP1 51, the LTP2 52, the LTP3 53, and the LTP4 54, to an STP 58, and the wafer W is then conveyed to the cleaning unit 4 through the STP 58.

Adjacently to the third polishing unit 3C and the fourth polishing unit 3D, the STP 58, an LTP5 55, an LTP6 56, and an LTP7 57 are provided. The wafer W is conveyed from the loading/unloading unit 2, through the LTP5 55, the LTP6 56, and the LTP7 57, to the third polishing unit 3C and the fourth polishing unit 3D. The wafer W having been polished by the polishing unit 3C and the fourth polishing unit 3D is conveyed, through the LTP5 55, the LTP6 56, and the LTP7 57, to the STP 58, and the wafer W is then conveyed to the cleaning unit 4 through the STP 58.

<Cleaning Unit>

The cleaning unit 4 is partitioned into first cleaning chambers (CL1A) 41, (CL1B) 42, a first conveying chamber (RB1) 43, second cleaning chambers (CL2A) 44, (CL2B) 45, a second conveying chamber (RB2) 46, and drying chambers (CL3A) 47, (CL3B) 48.

A primary cleaning module is disposed in each of the first cleaning chambers 41 and 42. The wafer W conveyed through the STP 58 is primarily cleaned by a primary cleaning module in the first cleaning chamber 41 or the first cleaning chamber 42.

The wafer W cleaned primarily is conveyed, through the first conveying chamber 43, to the second cleaning chamber 44 or the second cleaning chamber 45. A secondary cleaning module is disposed in each of the second cleaning chambers 44 and 45. The wafer W is secondarily cleaned by a secondary cleaning module in the second cleaning chamber 44 or the second cleaning chamber 45.

The wafer W cleaned secondarily is conveyed, through the second conveying chamber 46, to the drying chamber 47 or the drying chamber 48. A drying module is disposed in each of the drying chambers 47 and 48. The wafer W is dried by the drying module in the drying chamber 47 or the drying chamber 48. The dried wafer W is conveyed to the loading/unloading unit 2. As illustrated in FIG. 1, in the cleaning unit 4 of the CMP apparatus of the present embodiment, cleaning processing and drying processing each have two systems. Accordingly, effective cleaning processing and drying processing can be performed.

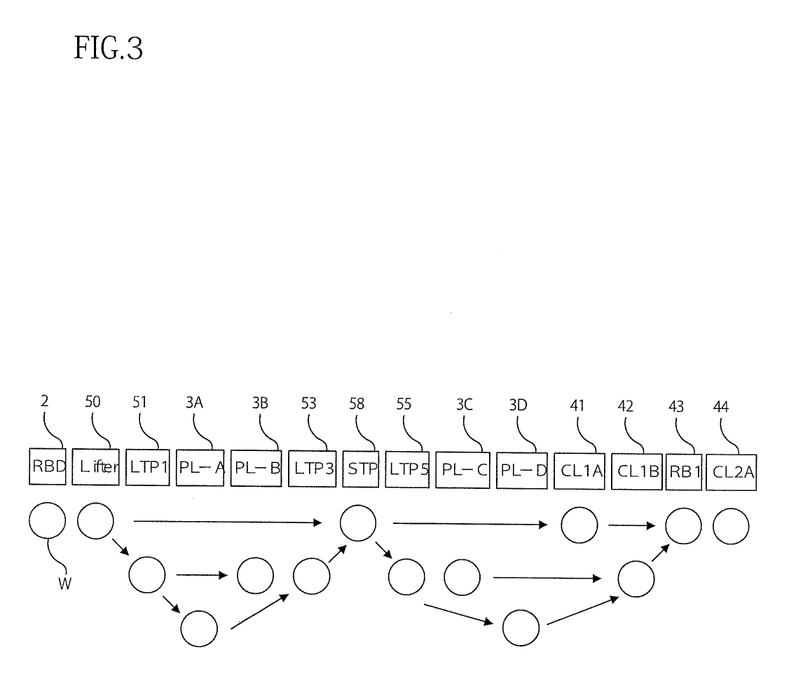

Next, descriptions will be given of a conveying route of the wafer W in the substrate processing apparatus. FIG. 3 is a diagram illustrating an example of a conveying route of the wafer W in the substrate processing apparatus.

As illustrated in FIG. 3, while being conveyed from the left unit (loading/unloading unit 2) to the right unit in FIG. 3, the wafer W is subjected to various kinds of processing. A conveying route of the wafer W changes in various ways depending on a recipe and a condition of the units set in the substrate processing apparatus. FIG. 3 illustrates three different conveying routes, for example, but an actual conveying route has a larger variety. The units illustrated in FIG. 3 are only one example, and another unit may be included in an actual substrate processing apparatus.

Here, if a malfunction occurs in any one of the units forming the substrate processing apparatus, a wafer W to pass through the malfunctioning unit afterwards is made to stand by on the spot, since the wafer W cannot advance to the next process.

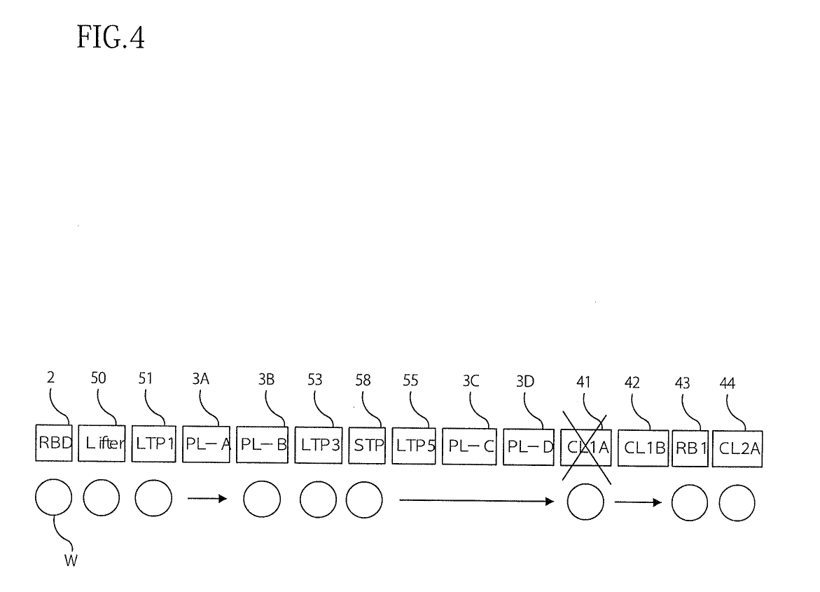

FIG. 4 is a diagram illustrating a state where conveying wafers W is delayed. FIG. 4 illustrates a state where a malfunction occurs in the first cleaning chamber 41 and wafers W to pass through the first cleaning chamber 41 afterwards are on standby since the wafers W cannot advance to the next process.

In the example of FIG. 4, the wafers W to pass through the first cleaning chamber 41 afterwards are on standby in the RBD 2, the Lifter 50, the LTP1 51, the second polishing unit 3B, the LTP3 53, and the STP 58, respectively. For example, even if the surfaces of the wafers W standing by in the RBD 2, the Lifter 50, the LTP1 51, and the second polishing unit 3B, respectively, are damaged in some degree due to generation of a standby time, these wafer surfaces are to be scraped in the subsequent polishing process, and thus, it hardly causes a problem, relatively.

In contrast, if, after the polishing process, the wafer W stands by in the LTP3 53 or the STP 58 in the state before advancing to the cleaning process, such wafer W is not preferable, since the surface thereof is damaged due to generation of a standby time.

Consequently, the substrate processing apparatus of the present embodiment has a function for monitoring standby times of each wafer W in each unit. Descriptions of this point will be given below.

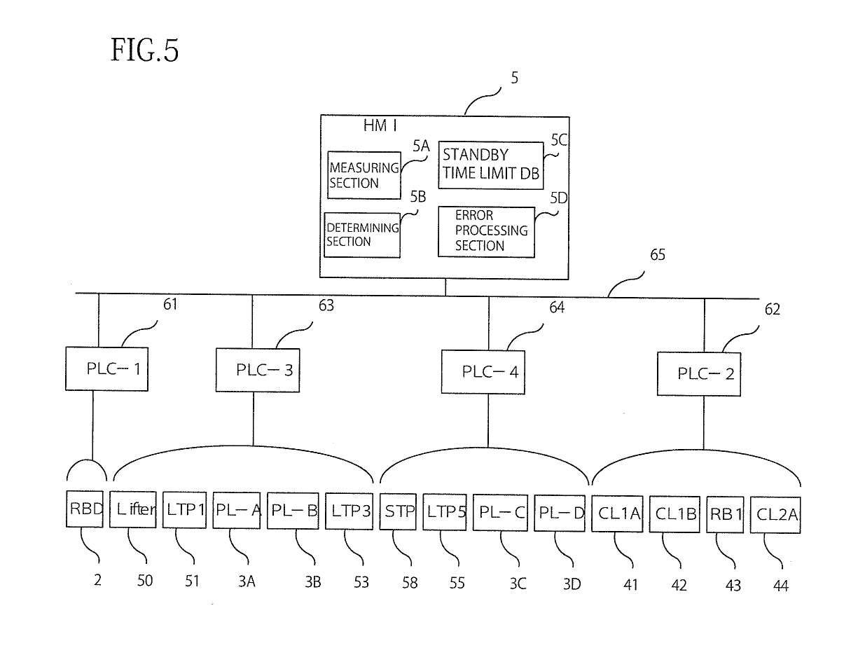

FIG. 5 is a diagram illustrating functional blocks of the substrate processing apparatus. As illustrate in FIG. 5, the substrate processing apparatus includes a PLC-1 61, a PLC-2 62, a PLC-3 63, and a PLC-4 64. The PLC-1 61 gathers various kinds of information about a wafer W in the RDB 2 (e.g., a time at which the wafer W enters the RDB 2, a time at which the wafer W leaves the RDB 2 for outside, etc.).

The PLC-2 62 gathers various kinds of information about wafers W in the units (for example, the first cleaning chambers 41, 42, the first conveying chamber 43, and the second cleaning chamber 44) included in the cleaning unit 4 (e.g., a time at which the wafer W enters the respective unit, a time at which the wafer W leaves the respective unit for outside, etc.).

The PLC-3 63 gathers various kinds of information about the wafers W in the units (for example, the Lifter 50, the LTP1 51, the first polishing unit 3A, the second polishing unit 3B, and the LTP1 53) included in the polishing unit 3 (e.g., a time at which the wafer W enters the respective unit, a time at which the wafer W leaves the respective unit for outside, etc.).

The PLC-4 64 gathers various kinds of information about the wafers W in the units (for example, the STP 58, the LTP5 55, the third polishing unit 3C, and the fourth polishing unit 3D) included in the polishing unit 3 (e.g., a time at which the wafer W enters the respective unit, a time at which the wafer W leaves the respective unit for outside, etc.).

Moreover, the substrate processing apparatus includes an HM 15. The various kinds of information gathered by the PLC-1 61, the ‘PLC-2 62, the PLC-3 63 and the PLC-4 64 are collected in the HM 15 through a CC-Link IE Network 65.

The HM 15 includes a measuring section 5A, a determining section 5B, a standby time limit DB 5C, and an error processing section 5D.

The measuring section 5A measures a standby time of each wafer W in each unit, based on the various kinds of information gathered by the PLC-1 61, the ‘PLC-2 62, the PLC-3 63 and the PLC-4 64.

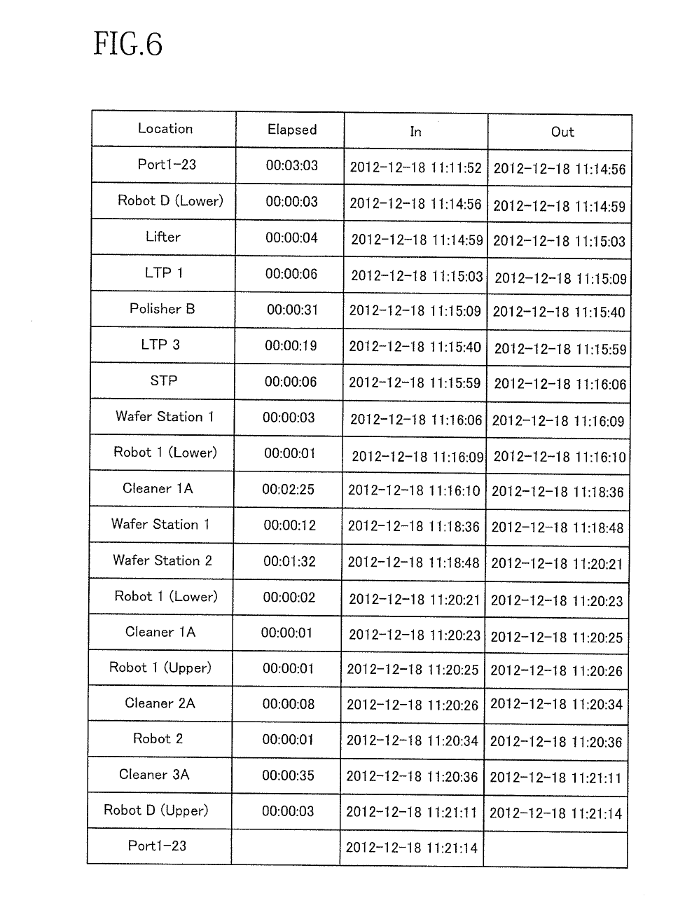

Here, descriptions will be given of a standby time of a wafer W in each unit. FIG. 6 is a diagram illustrating an example of standby times of a wafer in the units. FIG. 6 is a diagram illustrating an example of standby times of one certain wafer in the units.

As illustrated in FIG. 6, the measuring section 5A records times (In) at which the respective wafer W enters the respective unit (Location) and times (Out) at which the respective wafer W leaves the respective unit, based on the pieces of information gathered by the PLCs. Furthermore, the measuring section 5A measures a standby time (Elapsed) in the respective unit, based on the time at which each wafer W enters the unit and the time at which the wafer W leaves the unit.

The determining section 5B compares the standby time measured by the measuring section 5A and a set time preset in the standby time limit DB 50, set independently for each unit. If the standby time measured by the measuring section 5A exceeds the set time preset in the standby time limit DB 5C, the determining section 5B determines that an error occurs.

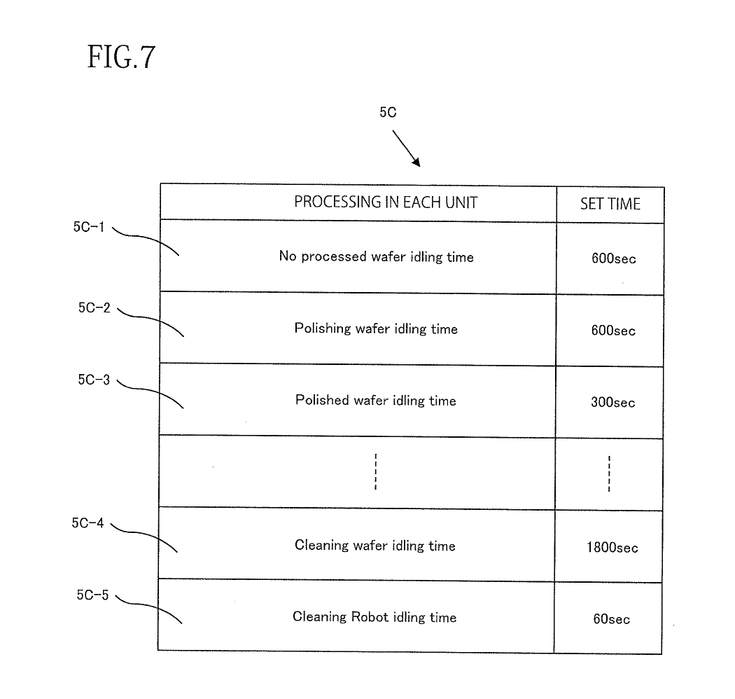

Here, descriptions will be given of the standby time limit DB 5C. FIG. 7 is a diagram illustrating an example of the standby time limit DB 5C. As illustrated in FIG. 7, a time period when a wafer W stands by in the Lifter 50, which is to convey the wafer W from the loading/unloading unit 2 to the polishing unit 3, is a state 5C-1 where no processing has been performed yet to the wafer W. In this state, a standby time limit is set to 600 (sec). Also, in a case where a wafer W stands by in any one of the polishing units 3A, 3B, 3C and 3D, and is in a state 5C-2 where the wafer W is being polished, for example, a standby time limit is set to 600 (sec).

In contrast to this, for example, in a case where a wafer W stands by in a conveying unit such as the LTP3 53, i.e., in a state 5C-3 which is before the cleaning process and after the polishing process, a standby time limit is set to 300 (sec).

In a state 5C-4 where a wafer W stands by in any one of the first cleaning chambers 41, 42, and the second cleaning chambers 44, 45, and the wafer W is being cleaned, a standby time limit is set to 1800 (sec).

In contrast to this, for example, in a case where a wafer W stands by in a conveying unit such as the second conveying chamber 46, i.e., in a state 5C-5 which is before the drying process and after the cleaning process, a standby time limit is set to 60 (sec).

As described so far, in the substrate processing apparatus, a time period in which a wafer W is allowed to stand by is varied depending on a state of the processing of the wafer W. Accordingly, a time limit can be independently set for each unit, in the present embodiment. If a standby time of each wafer W measured by the measuring section 5A exceeds a set time preset in the standby time limit DB 5C, the determining section 5B determines that an error occurs.

If the determining section 5B determines that an error occurs, the error processing section 5D displays an image representing the substrate processing apparatus on a displaying interface, and also displays an image specifying a unit in which a wafer W that is the error object stands by on the image representing the substrate processing apparatus.

That is, if the determining section 5B determines that an error occurs, the error processing section 5D issues an alert to attract a user's attention. Specifically, the error processing section 5D displays an image representing the substrate processing apparatus, as illustrated in FIG. 1, on the displaying interface. In the example of FIG. 1, an image 61 representing a wafer W is displayed on a region of the LTP3, whereby indicating that the wafer W is on standby in the LTP3 for a time period longer than the set time of 300 (sec).

If the determining section 5B determines that an error occurs, the error processing section 5D specifies a unit which causes the standby time to exceed the set time, among a plurality of units included in the image representing the substrate processing apparatus. Also, the error processing section 5D displays the specified unit such that the unit can be identified from the other units. For example, it is assumed that a wafer W is on standby in the LTP3 for a time period longer than the set time of 300 (sec) due to occurrence of a malfunction in the first cleaning chamber 41. In this case, the error processing section 5D displays “Down”, which indicates occurrence of the malfunction, at an upper part of the image representing the first cleaning chamber 41, as illustrated in FIG. 1.

Furthermore, if the determining section 5B determines that an error occurs, the error processing section 5D displays a conveying route of a wafer W that is the error object, on the displaying interface. For example, it is assumed that a wafer W is on standby in the LTP3 for a time period longer than the set time of 300 (sec). In this case, the error processing section 5D displays an arrow 62 extending from the image 61 representing the wafer W, as illustrated in FIG. 1, and thus, the error processing section 5D indicates a route to convey the wafer W standing by in the LTP3, through the STP 58, to the first cleaning chamber 41.

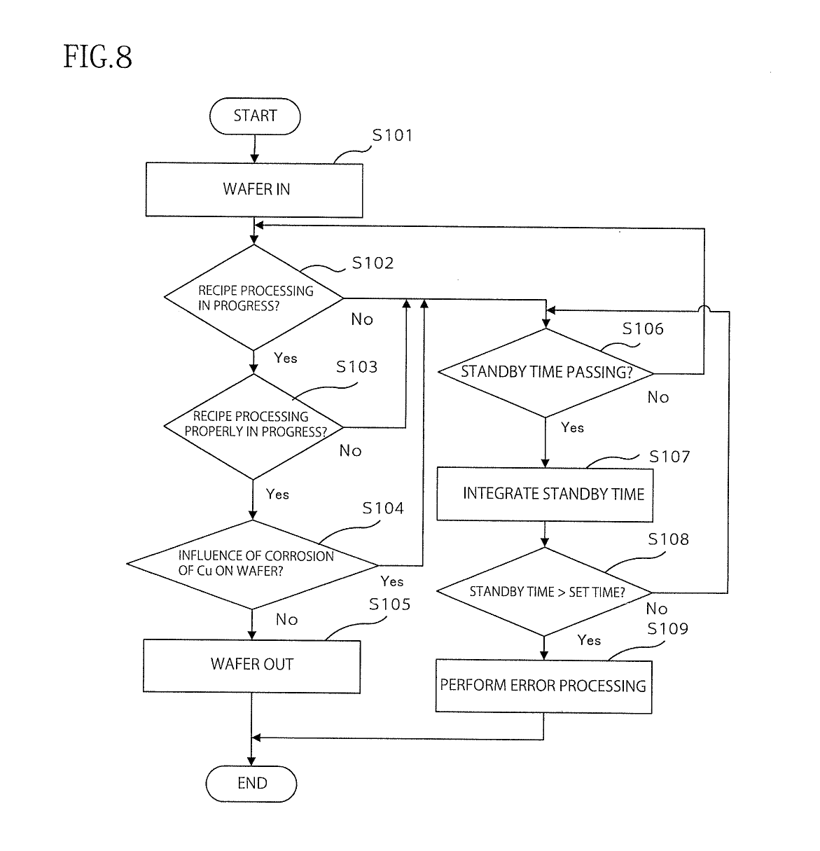

Next, descriptions will be given of a processing flow of the substrate processing apparatus. FIG. 8 is a diagram illustrating the processing flow of the substrate processing apparatus. The flow in FIG. 8 shows the processing to be performed from a time at which a wafer W enters each unit to a time at which the wafer W leaves the unit.

First, if the wafer W enters a unit (step S101), the measuring section 5A determines whether the recipe processing of the wafer W is in progress (step S102).

Thereafter, if the measuring section 5A determines that the recipe processing of the wafer W is in progress (Yes in step S102), the measuring section 5A determines whether the recipe processing is performed properly (step S103).

Thereafter, if the measuring section 5A determines that the recipe processing is performed properly (Yes in step S103), the measuring section 5A determines whether there is an influence of corrosion of Cu on the wafer W (step S104).

If the measuring section 5A determines that there is no influence of corrosion of Cu on the wafer W (No in step S104), the wafer W is taken out from the unit (step S105), and then, the processing is ended.

Meanwhile, the measuring section 5A determines that the recipe processing of the wafer W is not in progress (No in step S102), that the recipe processing is not performed properly (No in step S103), or that there is an influence of corrosion of Cu on the wafer W (Yes in step S104), the measuring section 5A determines whether the standby time of the wafer W is passing (step S106).

If the measuring section 5A determines that the standby time of the wafer W is not passing (No in step S106), the processing returns to step S102.

Meanwhile, the measuring section 5A determines that the standby time of the wafer W is passing (Yes in step S106), the measuring section 5A integrates (counts) the standby time (step S107).

Thereafter, the determining section 5B determines whether the integrated standby time has exceeded the set time (step S108). If the determining section 5B determines that the integrated standby time has not exceeded the set time (No in step S108), the processing returns to step S106.

Meanwhile, if the determining section 5B determines that the integrated standby time has exceeded the set time (Yes in step S108), the determining section 5B determines that an error occurs, and then, the error processing section 5D performs the error processing (step S109).

The error processing section 5D displays an image representing the substrate processing apparatus on the displaying interface, as illustrated in FIG. 1, for example. Moreover, the error processing section 5D displays an image specifying a unit in which a wafer W that is an error object stands by, whereby attracting a user's attention. Furthermore, the error processing section 5D can display the unit causing the error such that the unit can be identified from the other units, and also can display a conveying route of the wafer W that is the error object.

As described so far, according to the substrate processing apparatus of the present embodiment, a standby time in each unit is managed independently for each wafer W, and thus, it is possible to effectively suppress damage to a wafer in the substrate processing apparatus. Furthermore, in the substrate processing apparatus, a time period in which a wafer W is allowed to stand by is varied depending on a state of the processing of the wafer W. Accordingly, a time limit can be independently set for each unit, in the present embodiment. For this reason, it is possible to effectively suppress damage to a wafer in the substrate processing apparatus.

According to the present embodiment, in a case where an error occurs, an image specifying a unit in which a wafer W that is an error object stands by is displayed, whereby allowing a user to immediately recognize the position of the wafer W, which may be damaged. Moreover, according to the present embodiment, a unit causing an error is displayed such that the unit can be identified from the other units, and a conveying route of the wafer W that is an error object is displayed, whereby allowing a user to easily determine which unit affects occurrence of the error.

### REFERENCE SIGNS LIST

2 loading/unloading unit
3 polishing unit
4 cleaning unit
5 controlling section
5A measuring section
5B determining section
5C standby time limit DB
5D error processing section
22 conveying robot
43 RB1
46 RB2
50 Lifter
51 LTP1
52 LTP2
53 LTP3
54 LTP4
55 LTP5
56 LTP6
57 LTP7
58 STP

What is claimed is:

1. A substrate processing apparatus comprising:
a polishing unit configured to polish a substrate;
a cleaning unit configured to clean and dry the substrate polished by the polishing unit;
a conveying unit configured to convey the substrate in the polishing unit and the cleaning unit;
a measuring section configured to measure a standby time of each substrate for which the substrate stands by in each of the polishing unit, the cleaning unit, and the conveying unit; and
a determining section configured to compare the standby time measured by the measuring section and a set time set for the polishing unit, the cleaning unit and the conveying unit, independently, and determine that an error occurs if the standby time exceeds the set time.

2. The substrate processing apparatus of claim 1, further comprising:
a loading/unloading unit configured to deliver the substrate to the polishing unit and receive the substrate cleaned and dried by the cleaning unit,
wherein the conveying unit conveys the substrate in the polishing unit, the cleaning unit, the loading/unloading unit.

3. The substrate processing apparatus of claim 1, further comprising:
an error processing section configured to display, if the determining section determines that an error occurs, an image representing the substrate processing apparatus on a displaying interface, and display an image specifying a unit in which a substrate that is the error object is standing by on the image representing the substrate processing apparatus.

4. The substrate processing apparatus of claim 3, wherein
if the determining section determines that an error occurs, the error processing section specifies a unit causing the standby time to exceed the set time among a plurality of units included in the image representing the substrate processing apparatus, and displays the specified unit such that the unit can be identified from the other units.

5. The substrate processing apparatus of claim 3, wherein
if the determining section determines that an error occurs, the error processing section displays a conveying route of a substrate that is the error object on the displaying interface.
